(19) United States
(12) Patent Application Publication
(10) Pub. No.: US 2020/0052221 A1
(43) Pub. Date: Feb. 13, 2020

(54) ORGANIC ELECTROLUMINESCENT DEVICE

(71) Applicant: ROHM AND HAAS ELECTRONIC MATERIALS KOREA LTD., Chungcheongnam-do (KR)

(72) Inventors: Tae-Jin LEE, Gyeonggi-do (KR); Sang-Hee CHO, Gyeonggi-do (KR); Bitnari KIM, Gyeonggi-do (KR); Young-Jun CHO, Gyeonggi-do (KR)

(21) Appl. No.: 16/492,631

(22) PCT Filed: Mar. 29, 2018
(86) PCT No.: PCT/KR2018/003707

§ 371 Date: Sep. 10, 2019

(30) Foreign Application Priority Data
Apr. 3, 2017 (KR) 10-2017-0043143
Mar. 20, 2018 (KR) 10-2018-0031975

(51) Int. Cl. H01L 51/00

(52) U.S. Cl. CPC H01L 51/0061; H01L 51/0072; H01L 51/0073; H01L 51/5004; H01L 51/0085; H01L 51/0067; H01L 51/0074; H01L 51/006

(57) ABSTRACT

The present disclosure relates to an organic electroluminescent device. The organic electroluminescent device of the present disclosure can exhibit high efficiency and/or long lifespan by comprising at least specific combination of a light-emitting layer and a hole transport zone.

### TECHNICAL FIELD

The present disclosure relates to an organic electroluminescent device comprising a light-emitting layer and a hole transport zone.

### BACKGROUND ART

An electroluminescent device (EL device) is a self-light-emitting display device which has advantages in that it provides a wider viewing angle, a greater contrast ratio, and a faster response time. The first organic EL device was developed by Eastman Kodak in 1987, by using small aromatic diamine molecules and aluminum complexes as materials for forming a light-emitting layer (see Appl. Phys. Lett. 51, 913, 1987).

An organic EL device (OLED) changes electric energy into light by applying electricity to an organic electroluminescent material, and commonly comprises an anode, a cathode, and an organic layer formed between the two electrodes. The organic electroluminescent device has a multi-layer structure including a hole transport zone, a light-emitting layer, and an electron transport zone, etc., in order to improve its efficiency and stability. Specifically, the organic layer of the organic EL device may comprise a hole injection layer, a hole transport layer, a hole auxiliary layer, a light-emitting auxiliary layer, an electron blocking layer, a light-emitting layer (containing host and dopant materials), an electron buffer layer, a hole blocking layer, an electron transport layer, an electron injection layer, etc. The materials used in the organic layer can be classified into a hole injection material, a hole transport material, a hole auxiliary material, a light-emitting auxiliary material, an electron blocking material, a light-emitting material, an electron buffer material, a hole blocking material, an electron transport material, an electron injection material, etc., depending on their functions. In the organic EL device, holes from the anode and electrons from the cathode are injected into a light-emitting layer by the application of electric voltage, and excitons having high energy are produced by the recombination of the holes and electrons. The organic light-emitting compound moves into an excited state by the energy and emits light from an energy when the organic light-emitting compound returns to the ground state from the excited state.

The important factor determining luminous efficiency in an organic EL device is light-emitting materials. The light-emitting materials are required to have the following features: high quantum efficiency, high movement degree of an electron and a hole, and uniformality and stability of the formed light-emitting material layer. In addition, it is preferable that the compound comprised in a hole transport zone and/or an electron transport zone can improve device characteristics such as hole transport efficiency or electron transport efficiency to the light-emitting layer, light-emitting efficiency, and lifespan time.

Copper phthalocyanine (CuPc), 4,4′-bis[N-(1-naphthyl)-N-phenylamino]biphenyl (NPB), N,N′-diphenyl-N,N′-bis(3-methylphenyl)-(1,1′-biphenyl)-4,4′-diamine (TPD), 4,4′,4″-tris(3-methylphenylphenylamino)triphenylamine (MTDATA), etc., were used as compounds comprised in a hole transport zone in an organic EL device. However, an organic EL device using these materials has problems of reduction in quantum efficiency and lifespan. It is because, when an organic EL device is driven under high current, thermal stress occurs between an anode and a hole injection layer. Such thermal stress significantly reduces the lifespan of the device. Further, since the organic material used in the hole transport zone has very high hole mobility, the hole-electron charge balance may be broken and quantum yield (cd/A) may decrease.

Meanwhile, a compound comprised in an electron transport zone in an organic EL device smoothly transfers electrons from the cathode to the light-emitting layer and inhibits the movement of holes that are not bonded in the light-emitting layer, so that the compound increases the chance of recombination of holes and electrons in the light-emitting layer. Further, a compound comprised in an electron transport zone is required to exhibit high electron mobility characteristics when used in organic electroluminescent devices due to their high electron affinity, thereby, to have a material providing organic EL devices having high luminous efficiency.

That is, development of compounds comprised in a light-emitting layer, a hole transport zone and/or an electron transport zone is still required in order to improve the performance of an organic EL device.

Korean Patent Appln. Laying-Open Nos. 2015-0071685 and 2015-0135109 disclose an OLED device using a quinoxaline derivative compound as a host; however, they do not specifically disclose that the performance of an OLED device can be improved by combining such a host compound with a specific material comprised in a hole transport zone and/or an electron transport zone.

### DISCLOSURE OF THE INVENTION

### Problems to be Solved

The object of the present disclosure is to provide an organic electroluminescent device having high efficiency and/or long lifespan by comprising at least a specific combination of a light-emitting layer and a hole transport zone.

### Solution to Problems

As LUMO core of a host compound comprised in a light-emitting layer, quinoxaline derivatives disclosed in prior art documents are likely to exhibit a concentration-quenching phenomenon due to having a relatively superior electron balance. In order to reduce such a concentration-quenching phenomenon, there is a need to compensate for charge being leaned to one side, i.e., electrons. The present inventors found that the efficiency and/or lifespan of an organic electroluminescent device can be improved by reducing the concentration-quenching phenomenon and smoothly injecting holes through combining a light-emitting layer comprising quinoxaline derivatives with a hole transport zone comprising a compound(s) having specific HOMO and LUMO energy levels, and completed the present invention. Specifically, the aforementioned objective can be achieved by an organic electroluminescent device comprising a first electrode; a second electrode facing the first electrode; a light-emitting layer between the first electrode and the second electrode; a hole transport zone comprising a plurality of hole transport layers between the first electrode and the light-emitting layer; and an electron transport zone between the light-emitting layer and the second electrode, wherein the light-emitting layer comprises quinoxaline derivatives, and wherein a hole transport layer adjacent to the light-emitting layer among the plurality of hole transport layers comprises a compound(s) having HOMO and LUMO energy levels satisfied by the following Equations 1 and 2, respectively.

−4.9 eV≤HOMO≤−4.7 eV (1)

LUMO≤−1.0 eV (2)

### Effects of the Invention

According to the present disclosure, an organic electroluminescent device having high efficiency and/or long lifespan is provided, and a display device or a lighting device using the same can be produced.

### EMBODIMENTS OF THE INVENTION

Hereinafter, the present disclosure will be described in detail. However, the following description is intended to explain the invention, and is not meant in any way to restrict the scope of the invention.

An organic electroluminescent device of the present disclosure comprises a first electrode; a second electrode facing the first electrode; a light-emitting layer between the first electrode and the second electrode; a hole transport zone comprising a plurality of hole transport layers between the first electrode and the light-emitting layer; and an electron transport zone between the light-emitting layer and the second electrode. One of the first electrode and the second electrode may be an anode, the other may be a cathode.

The hole transport zone is meant to be a zone where holes move between the first electrode and the light-emitting layer, and may further comprise at least one of a hole injection layer, a hole auxiliary layer, a light-emitting auxiliary layer, and an electron blocking layer. The hole injection layer, the hole auxiliary layer, the light-emitting auxiliary layer, and the electron blocking layer may be a single layer or a multi-layer of which two or more layers are stacked.

According to one embodiment of the present disclosure, the hole transport zone may further comprise a hole transport layer as well as at least one of a hole injection layer, a hole auxiliary layer, a light-emitting auxiliary layer, and an electron blocking layer. The hole transport layer may be placed between the anode (or the hole injection layer) and the light-emitting layer. The hole transport layer smoothly moves the holes transferred from the anode to the light-emitting layer, and blocks the electrons transferred from the cathode to remain in the light-emitting layer. The light-emitting auxiliary layer may be placed between the anode and the light-emitting layer, or between the cathode and the light-emitting layer. When the light-emitting auxiliary layer is placed between the anode and the light-emitting layer, it can be used for promoting the hole injection and/or the hole transport, or for preventing the overflow of electrons. When the light-emitting auxiliary layer is placed between the cathode and the light-emitting layer, it can be used for promoting the electron injection and/or the electron transport, or for preventing the overflow of holes. Also, the hole auxiliary layer may be placed between the hole transport layer (or hole injection layer) and the light-emitting layer, and may be effective to promote or block the hole transport rate (or the hole injection rate), thereby enabling the charge balance to be controlled. Also, the electron blocking layer may be placed between the hole transport layer (or the hole injection layer) and the light-emitting layer, and can confine the excitons within the light-emitting layer by blocking the overflow of electrons from the light-emitting layer to prevent a light-emitting leakage. When an organic electroluminescent device includes two or more hole transport layers, the hole transport layer, which is further included, can be used for a hole auxiliary layer or an electron blocking layer. The light-emitting auxiliary layer, the hole auxiliary layer, or the electron blocking layer may have an effect of improving the efficiency and/or lifespan of an organic electroluminescent device.

The electron transport zone is meant to be a zone where holes move between the second electrode and the light-emitting layer, and may further comprise at least one of an electron buffer layer, a hole blocking layer, an electron transport layer, and an electron injection layer, preferably, at least one of an electron buffer layer, an electron transport layer and an electron injection layer. An electron buffer layer is a layer for solving the problem of a change in luminance caused by the change of a current characteristic of the device when exposed to a high temperature during a process of producing a panel, and may control the charge flow characteristics.

The light-emitting layer is a layer from which light is emitted, and may be a single layer or a multi-layer of which two or more layers are stacked. In the light-emitting layer, it is preferable that the doping concentration of the dopant compound based on the host compound is less than 20 wt %.

A first embodiment of an organic electroluminescent device according to the present disclosure comprises quinoxaline derivatives in a light-emitting layer, and a compound(s) having HOMO and LUMO energy levels satisfied by the following Equations 1 and 2, respectively, in the hole transport layer adjacent to the light-emitting layer among the plurality of hole transport layers.

−5.0 eV≤HOMO≤−4.7 eV (1)

LUMO≤−1.0 eV (2)

In a hole transport zone of the present disclosure, e.g., when the hole transport layer adjacent to the light-emitting layer among the plurality of hole transport layers comprises a compound having greater than −4.7 eV of a HOMO energy value, injection and/or transport of holes from the anode to the hole transport zone may not be smooth. When the hole transport layer adjacent to the light-emitting layer among the plurality of hole transport layers comprises a compound having less than −5.0 eV of a HOMO energy value, injection and/or transport of holes from the hole transport zone to the light-emitting layer may not be smooth. Also, the overflow of holes from the light-emitting layer may occur. Thus, in the case where the hole transport layer adjacent to the light-emitting layer among the plurality of hole transport layers comprises a compound having a HOMO energy value between −5.0 eV or and −4.7 eV, it is possible to improve the current efficiency by smoothly injecting and/or transporting holes, thereby improving the efficiency and/or lifespan characteristics of the organic electroluminescent device.

According to a first embodiment of the present disclosure, in order to improve the efficiency and/or lifespan characteristics of an organic electroluminescent device, the hole transport layer adjacent to the light-emitting layer may comprise a compound having a HOMO energy level satisfied by the following Equation 4.

−4.9 eV≤HOMO≤−4.7 eV (4)

Meanwhile, in a hole transport zone, e.g., when the hole transport layer adjacent to the light-emitting layer among the plurality of hole transport layers comprises a compound having −1.0 eV or less of a LUMO energy value, it is possible to more effectively block the overflow of electrons from the light-emitting layer, and/or further improve the current efficiency, thereby improving the efficiency and lifespan characteristics of the organic electroluminescent device. In addition, according to one embodiment of the present disclosure, a compound comprised in the hole transport layer adjacent to the light-emitting layer among the plurality of hole transport layers has LUMO energy levels larger than a compound comprised in the light-emitting layer thereof. Thus, transport of an electron from the light-emitting layer to the hole transport zone may be blocked. According to one embodiment of the present disclosure, the hole transport layer adjacent to the light-emitting layer may comprise a compound having −1.4 eV to −1.0 eV of LUMO energy level.

According to a second embodiment of the present disclosure, in the hole transport zone according to the first embodiment, e.g., the hole transport layer adjacent to the light-emitting layer may comprise at least one carbazole-based arylamine derivative and at least one arylamine derivative that does not contain carbazole, wherein each of the carbazole-based arylamine derivatives may be the same or different from each other, and each of the arylamine derivatives not containing carbazole may be the same or different from each other.

According to a third embodiment of the present disclosure, in the first or the second embodiment, at least one carbazole-based arylamine derivative comprised in the hole transport layer adjacent to the light-emitting layer may contain at least one of the compounds represented by the following formulae 1 and 2.

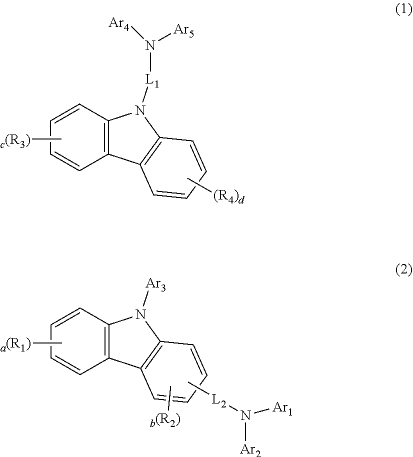

In formulae 1 and 2, Aᵣ to Ar₅ each independently represent a substituted or unsubstituted (C6-C30)aryl, or a substituted or unsubstituted (5- to 30-membered)heteroaryl, preferably, each independently represent a substituted or unsubstituted (C6-C25)aryl, or a substituted or unsubstituted (5- to 25-membered)heteroaryl, more preferably, each independently represent a substituted or unsubstituted (C6-C18)aryl, or a substituted or unsubstituted (5- to 18-membered)heteroaryl. According to one embodiment of the present disclosure, in the formula 2, Aᵣ and Ar₂ may each independently be unsubstituted phenyl, phenylcarbazolylphenylamino-substituted or unsubstituted biphenyl, or dimethylfluorenyl; and Ar₃ may be unsubstituted phenyl.

In formulae 1 and 2, L₁ and L₂ each independently represent a single bond or a substituted or unsubstituted (C6-C30)arylene, preferably, each independently represent a single bond or a substituted or unsubstituted (C6-C25)arylene, more preferably, each independently represent a single bond or an unsubstituted (C6-C18)arylene. According to one embodiment of the present disclosure, in formula 2, L₂ may be a single bond or unsubstituted phenylene.

In formulae 1 and 2, R, to R₄ each independently represent hydrogen, deuterium, halogen, a substituted or unsubstituted (C1-C30)alkyl, a substituted or unsubstituted (C6-C30)aryl, a substituted or unsubstituted (5- to 30-membered)heteroaryl, a substituted or unsubstituted (C3-C30)cycloalkyl, a substituted or unsubstituted (3- to 7-membered) heterocycloalkyl, a substituted or unsubstituted (C6-C30)ar(C1-C30)alkyl, —NR₁₁R₁₂, —SiR₁₃R₁₄R₁₅, —SR₁₆, —OR₁₇, cyano, nitro, or hydroxy; or may be linked to an adjacent substituent to form a substituted or unsubstituted, (C3-C30) mono- or polycyclic, alicyclic, aromatic ring, or the combination thereof, whose carbon atom may be replaced with at least one heteroatom selected from nitrogen, oxygen, and sulfur, preferably, each independently represent hydrogen, halogen, a substituted or unsubstituted (C1-C6)alkyl, a substituted or unsubstituted (C6-C18)aryl, a substituted or unsubstituted (5- to 25-membered)heteroaryl, or a substituted or unsubstituted (C6-C18)ar(C1-C6)alkyl. According to one embodiment of the present disclosure, in formula 2, both R, and R₂ may be hydrogen.

In formulae 1 and 2, R₁₁ to R₁₇ each independently represent hydrogen, deuterium, halogen, a substituted or unsubstituted (C1-C30)alkyl, a substituted or unsubstituted (C6-C30)aryl, a substituted or unsubstituted (5- to 30-membered)heteroaryl, a substituted or unsubstituted (3- to 7-membered)heterocycloalkyl, or a substituted or unsubstituted (C3-C30)cycloalkyl; or may be linked to an adjacent substituent to form a substituted or unsubstituted, (C3-C30) mono- or polycyclic, alicyclic, aromatic ring, or the combination thereof, whose carbon atom may be replaced with at least one heteroatom selected from nitrogen, oxygen, and sulfur.

In formulae 1 and 2, a, c and d each independently represent an integer of 1 to 4, b represents an integer of 1 to 3, and where a to d each represent an integer of 2 or more, each of R, to R₄ may be the same or different, preferably, a to d each independently represent 1 or 2. According to one embodiment of the present disclosure, in formula 2, both a and b may be 1.

The heteroaryl contains at least one heteroatom selected from B, N, O, S, Si, and P, preferably, at least one N.

According to a fourth embodiment of the present disclosure, in the one of the first to third embodiments, at least one of the arylamine derivative not containing carbazole comprised in the hole transport layer adjacent to the light-emitting layer may contain at least one of the compounds represented by the following formulae 3 and 4.

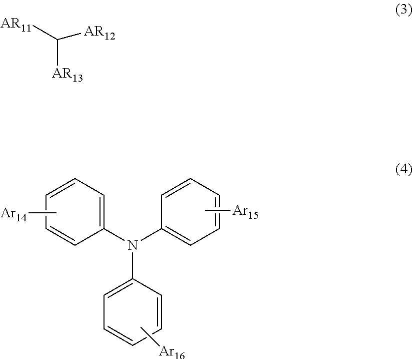

In formula 3, Ar₁₁ to Ar₁₃ each independently represent a substituted or unsubstituted (C6-C30)aryl, or a substituted or unsubstituted (5- to 50-membered)heteroaryl, provided that at least one of Ar₁ to Ar₁₃ contains a fluorene derivative, preferably, each independently represent a substituted or unsubstituted (C6-C30)aryl, or a substituted or unsubstituted (5- to 35-membered)heteroaryl, wherein the substituent of a substituted aryl may be at least one of (C1-C6)alkyl, (C6-C18)aryl, and di(C6-C18)arylamino. According to one embodiment of the present disclosure, Ar₁₁ to Ar₁₃ each independently may be unsubstituted phenyl, unsubstituted biphenyl, phenylbiphenylamino-substituted or unsubstituted dimethylfluorenyl, dimethylfluorenylphenylamino-substituted or unsubstituted diphenylfluorenyl, dimethylbenzofluorenyl, spiro[fluorene-benzofluorene]yl, or spiro[benzofuranylfluorene-fluorene]yl.

In formula 4, Ar₁₄ to Ar₁₆ each independently represent a substituted or unsubstituted (C6-C30)aryl, a substituted or unsubstituted (5- to 30-membered)heteroaryl, or a substituted or unsubstituted (C6-C30)arylamine; or may be linked to an adjacent substituent to form a substituted or unsubstituted ring.

The heteroaryl contains at least one heteroatom selected from B, N, O, S, Si, and P, preferably, at least one heteroatom selected from N and O.

According to a fifth embodiment of the present disclosure, in the one of the first to fourth embodiments, an electron transport zone may comprise a compound having LUMO energy levels (Ae) satisfied by the following Equation 3.

Ae≤−1.5 eV (3)

When an electron transport zone of the present disclosure comprises a compound having greater than −1.5 eV of LUMO energy level, injection and/or transport of an electron to a light-emitting layer may not be smooth. Also, the overflow of electrons from the light-emitting layer may occur; thus, in the case where the electron transport zone comprises a compound having −1.5 eV or less of LUMO energy level, the current efficiency can be improved by facilitating the injection and/or transport of electrons, thereby improving the efficiency and/or lifespan characteristics of the organic electroluminescent device of the present disclosure.

In the fifth embodiment of the present disclosure, the electron transport zone of the present disclosure, for high efficiency and/or long lifespan of an organic electroluminescent device, may comprise a compound having a LUMO energy level (Ae) satisfied by the following Equation 5, more preferably, may comprise a compound having a LUMO energy level (Ae) satisfied by the following Equation 6.

Ae≤−1.8 eV (5)

Ae≤−1.85 eV (6)

According to a sixth embodiment of the present disclosure, in the one of the first to fifth embodiments, the electron transport zone comprises at least one triazine derivative, wherein each of the triazine derivatives may be the same or different from each other.

According to a seventh embodiment of the present disclosure, in the one of the first to sixth embodiments, at least one triazine derivative comprised in the electron transport zone comprises a compound represented by formula 5.

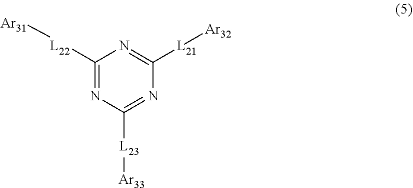

In formula 5, L₂₁ to L₂₃ each independently represent a single bond, a substituted or unsubstituted (C6-C50)arylene, or a substituted or unsubstituted (5- to 50-membered)heteroarylene, preferably, each independently represent a single bond, a substituted or unsubstituted (C6-C30)arylene, or a substituted or unsubstituted (5- to 30-membered)heteroarylene, more preferably, each independently represent a single bond, (5- to 30-membered)heteroarylene-substituted or unsubstituted (C6-C18)arylene, or unsubstituted (5- to 25-membered)heteroarylene. According to one embodiment of the present disclosure, L₂₁ to L₂₃ each independently may be a single bond, pyridine-substituted or unsubstituted phenylene, unsubstituted naphthylene, unsubstituted biphenylene, or a 17-membered heteroarylene containing nitrogen and/or oxygen.

In formula 5, Ar₃₁ to Ar₃₃ each independently represent hydrogen, deuterium, a substituted or unsubstituted (C6-C50)aryl, or a substituted or unsubstituted (5- to 50-membered)heteroaryl, preferably, each independently represent hydrogen, a substituted or unsubstituted (C6-C30)aryl, or a substituted or unsubstituted (5- to 45-membered)heteroaryl, more preferably, each independently represent a (C1-C10)alkyl-substituted or unsubstituted (C6-C18)aryl, or (C6-C18)aryl-substituted or unsubstituted (5- to 40-membered)heteroaryl. According to one embodiment of the present disclosure, Ar₃₁ to Ar₃₃ each independently may be phenyl, naphthalenyl, dimethylfluorenyl, phenanthrenyl, benzoimidazolyl substituted with phenyl, quinolinyl, benzocarbazolyl, dibenzocarbazolyl, or a 32-membered heteroaryl containing sulfur (including spiro structure).

The heteroaryl(ene) contains at least one heteroatom selected from B, N, O, S, Si, and P.

Herein, “(C1-C30)alkyl” is meant to be a linear or branched alkyl having 1 to 30 carbon atoms constituting the chain, in which the number of carbon atoms is preferably 1 to 10, more preferably 1 to 6, and includes methyl, ethyl, n-propyl, isopropyl, n-butyl, isobutyl, and tert-butyl, etc. “(C3-C30)cycloalkyl” is meant to be a mono- or polycyclic hydrocarbon having 3 to 30 ring backbone carbon atoms, in which the number of carbon atoms is preferably 3 to 20, and more preferably 3 to 7, and includes cyclopropyl, cyclobutyl, cyclopentyl, cyclohexyl, etc. “(3- to 7-membered)heterocycloalkyl” is meant to be a cycloalkyl having 3 to 7, ring backbone atoms, including at least one heteroatom selected from the group consisting of B, N, O, S, Si, and P, and preferably O, S, and N, and includes tetrahydrofuran, pyrrolidine, thiolane, tetrahydropyran, etc. “(C6-C50)aryl(ene)” is meant to be a monocyclic or fused ring radical derived from an aromatic hydrocarbon having 6 to 50 ring backbone carbon atoms, in which the number of the ring backbone carbon atoms is preferably 6 to 30, more preferably 6 to 20, may be partially saturated. The aryl includes phenyl, biphenyl, terphenyl, naphthyl, binaphthyl, phenylnaphthyl, naphthylphenyl, fluorenyl, phenylfluorenyl, benzofluorenyl, dibenzofluorenyl, phenanthrenyl, phenylphenanthrenyl, anthracenyl, indenyl, triphenylenyl, pyrenyl, tetracenyl, perylenyl, chrysenyl, naphthacenyl, fluoranthenyl, etc. “(5- to 50-membered)heteroaryl(ene)” is meant to be an aryl group having at least one heteroatom selected from the group consisting of B, N, O, S, Si, and P, and having 5 to 50, preferably 5 to 40, and more preferably 5 to 30 ring backbone atoms; having preferably 1 to 4 heteroatoms, and may be a monocyclic ring, or a fused ring condensed with at least one benzene ring; may be partially saturated. In addition, the heteroaryl(ene) may be one formed by linking at least one heteroaryl or aryl group to a heteroaryl group via a single bond(s); and may include a spiro structure. The heteroaryl includes a monocyclic ring-type heteroaryl such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridinyl, pyrazinyl, pyrimidinyl, pyridazinyl, etc., and a fused ring-type heteroaryl such as benzofuranyl, benzothiophenyl, isobenzofuranyl, dibenzofuranyl, dibenzothiophenyl, benzonaphtothiophenyl, benzoimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, phenoxazinyl, phenanthridinyl, benzodioxolyl, etc. “Halogen” includes F, Cl, Br, and I.

Herein, “substituted or unsubstituted ring” is meant to be a substituted or unsubstituted, (C3-C30) mono- or polycyclic, alicyclic, aromatic ring or the combination thereof, preferably, may be a substituted or unsubstituted, (C5-C25) mono- or polycyclic, alicyclic, aromatic ring or the combination thereof, more preferably, may be (C5-C18) mono- or polycyclic, alicyclic, aromatic ring or the combination thereof.

In addition, “substituted” in the expression “substituted or unsubstituted” means that a hydrogen atom is replaced with another atom or functional group (i.e., a substituent) in a certain functional group. The substituents of the substituted alkyl, the substituted aryl(ene), the substituted heteroaryl(ene), the substituted cycloalkyl, the substituted heterocycloalkyl, the substituted aralkyl, the substituted arylamine, and the substituted mono- or polycyclic, alicyclic, aromatic ring or the combination thereof, in Aᵣ to Ar₅, L₁, L₂, R, to R₄, R₁₁ to R₁₇, Ar₁ to Ar₁₆, L₂₁ to L₂₃, and Ar₃₁ to Ar₃₃ of formulae 1 to 5, are each independently at least one selected from the group consisting of deuterium; halogen; cyano; carboxyl; nitro; hydroxy; (C1-C30)alkyl; halo(C1-C30)alkyl; (C2-C30)alkenyl; (C2-C30)alkynyl; (C1-C30)alkoxy; (C1-C30)alkylthio; (C3-C30)cycloalkyl; (C3-C30)cycloalkenyl; (3- to 7-membered)heterocycloalkyl; (C6-C30)aryloxy; (C6-C30)arylthio; (C1-C30)alkyl- and/or (3- to 50-membered)heteroaryl-substituted or unsubstituted (C6-C30)aryl; (C1-C30)alkyl- and/or (C6-C30)aryl-substituted or unsubstituted (5- to 50-membered)heteroaryl; tri(C1-C30)alkylsilyl; tri(C6-C30)arylsilyl; di(C1-C30)alkyl(C6-C30)arylsilyl; (C1-C30)alkyldi(C6-C30)arylsilyl; amino; a mono- or di-(C1-C30)alkylamino; (C1-C30)alkyl- and/or (C6-C30)aryl-substituted or unsubstituted mono- or di-(C6-C30)arylamino; (C1-C30)alkyl(C6-C30)arylamino; (C1-C30)alkylcarbonyl; (C1-C30)alkoxycarbonyl; (C6-C30)arylcarbonyl; di(C6-C30)arylboronyl; di(C1-C30)alkylboronyl; (C1-C30)alkyl(C6-C30)arylboronyl; (C6-C30)ar(C1-C30)alkyl; and (C1-C30)alkyl(C6-C30)aryl, preferably, are each independently at least one selected from the group consisting of (C1-C20)alkyl; (C6-C25)aryl; (5- to 30-membered)heteroaryl; amino; a mono- or di-(C1-C30)alkylamino; and (C1-C6)alkyl- and/or (C6-C18)aryl-substituted or unsubstituted mono- or di-(C6-C25)arylamino, more preferably, are each independently at least one selected from the group consisting of (C1-C6)alkyl; (C6-C18)aryl; (5- to 25-membered)heteroaryl; and di(C6-C25)arylamino substituted with (C6-C18)aryl, whose carbon atom(s) may be replaced with at least one heteroatom selected from B, N, O, S, Si, and P. According to one embodiment of the present disclosure, the substituents may be at least one selected from the group consisting of methyl, phenyl, pyridinyl, biphenylphenylamino, phenylcarbazolylphenylamino, and dimethylfluorenylphenylamino.

The organic electroluminescent device of the present disclosure can be used for the manufacture of display devices such as smartphones, tablets, notebooks, PCs, TVs, or display devices for vehicles, or lighting devices such as an outdoor or indoor lighting.

The organic electroluminescent device of the present disclosure is an embodiment in which the description of the present disclosure is provided so as to be sufficiently delivered to one skilled in the art, but the present disclosure should not be limited to the embodiment. Also, the present disclosure can be embodied in other forms.

HOMO and LUMO energy levels of the present disclosure were calculated by using the density functional theory (DFT) in Gaussian 03 program (Gaussian. Inc.), but are not limited thereto. Specifically, HOMO and LUMO energy values in the examples and comparative examples of the present disclosure were derived from the structure with the lowest energy by comparing the energy of the calculated conformer after optimizing the structure of all possible forms of isomeric at B3LYP/6-31g* level.

Hereinafter, in order to grasp the electron current characteristic of the host LUMO core, an electron only device (EOD) was produced as to the LUMO core that determines the LUMO energy value of the host comprised in the light-emitting layer.

### [EOD Examples 1 to 3] Producing an EOD Comprising a LUMO Core Compound

An EOD comprising a LUMO core compound was produced. First, a transparent electrode indium tin oxide (ITO) thin film (10 Ω/sq) on a glass substrate for an OLED (GEOMATEC CO., LTD., Japan) was subjected to an ultrasonic washing with acetone, ethanol, and distilled water, sequentially, and then was stored in isopropanol. Next, the ITO substrate was mounted on a substrate holder of a vacuum vapor deposition apparatus. Compound HBL was introduced into a cell of the vacuum vapor deposition apparatus, and the pressure in the chamber of the apparatus was then controlled to 10⁻⁶ torr. Thereafter, an electric current was applied to the cell to evaporate the introduced material, thereby forming a hole blocking layer having a thickness of 10 nm on the ITO substrate. Next, a light-emitting layer was then deposited as follows. The compound described in the following Table 1 as a host was introduced into one cell of the vacuum vapor deposition apparatus and compound RD-1 as a dopant was introduced into another cell of the apparatus. The two materials were evaporated and the dopant was deposited in a doping amount of 3 wt %, based on the total weight of the host and dopant, to form a light-emitting layer having a thickness of 40 nm on the hole blocking layer. Compound ET-1 and compound EI-1 were then introduced into the other two cells, and respectively evaporated at a rate of 1:1 to form an electron transport layer having a thickness of 30 nm on the light-emitting layer. After depositing compound EI-1 as an electron injection layer having a thickness of 2 nm on the electron transport layer, an Al cathode having a thickness of 80 nm was deposited on the electron injection layer by another vacuum vapor deposition apparatus. Thus, an EOD device was produced.

The voltage at a current density of 10 mA/cm² of EOD Examples 1 to 3 as produced above is shown in the following Table 1.

TABLE 1

| | Host | Voltage (V) |
|---|---|---|
| EOD Example 1 | RH-1 | 3.9 |
| EOD Example 2 | RH-2 | 4.6 |
| EOD Example 3 | RH-3 | 5.4 |

From EOD Examples 1 to 3 above, it can be seen that the voltage at a constant current density, i.e., the electron current characteristic differs according to the LUMO moiety. Specifically, the electron current characteristic of quinoxaline derivative (EOD Example 2) of the present disclosure is faster than the quinazoline derivative (EOD Example 3), and slower than triazine derivative (EOD Example 1). From the results above, quinoxaline derivative of the present disclosure has a relatively superior electron balance than the quinazoline derivative, and thus a concentration-quenching phenomenon may occur due to the emission zone being inclined toward the hole transport layer in the light-emitting layer.

Hereinafter, it will be examined whether the combination quinoxaline derivative as a host compound and a hole transport zone having specific HOMO and LUMO levels can improve the efficiency and/or lifespan. However, the following examples are merely explained of the characteristics of the OLED device according to the present disclosure in order to understand the present disclosure in detail, but the present disclosure should not be limited to the following embodiment.

### [Device Examples 1-1 to 1-6] Producing an OLED Device According to the Present Disclosure

An OLED device according to the present disclosure was produced. First, a transparent electrode indium tin oxide (ITO) thin film (10 Ω/sq) on a glass substrate for an OLED (GEOMATEC CO., LTD., Japan) was subjected to an ultrasonic washing with acetone, ethanol, and distilled water, sequentially, and then was stored in isopropanol. Next, the ITO substrate was mounted on a substrate holder of a vacuum vapor deposition apparatus. Compound HI-1 was introduced into a cell of the vacuum vapor deposition apparatus, and the pressure in the chamber of the apparatus was then controlled to 10⁻⁶ torr. Thereafter, an electric current was applied to the cell to evaporate the introduced material, thereby forming a first hole injection layer having a thickness of 90 nm on the ITO substrate. Compound HI-2 was then introduced into another cell of the vacuum vapor deposition apparatus, and an electric current was applied to the cell to evaporate the introduced material, thereby forming a second hole injection layer having a thickness of 5 nm on the first hole injection layer. Next, compound HT-1 was introduced into one cell of the vacuum vapor deposition apparatus. Thereafter, an electric current was applied to the cell to evaporate the introduced material, thereby forming a first hole transport layer having a thickness of 10 nm on the second hole injection layer. The compound described in the following Table 2 was then introduced into another cell of the vacuum vapor deposition apparatus, and an electric current was applied to the cell to evaporate the introduced material, thereby forming a second hole transport layer having a thickness of 60 nm on the first hole transport layer. After forming the hole injection layers and the hole transport layers, a light-emitting layer was then deposited as follows. The compound described in the following Table 2 as a host was introduced into one cell of the vacuum vapor deposition apparatus and compound RD-1 as a dopant was introduced into another cell of the apparatus. The two materials were evaporated and the dopant was deposited in a doping amount of 2 wt %, based on the total weight of the host and dopant, to form a light-emitting layer having a thickness of 40 nm on the second hole transport layer. Next, Compound ET-1 and compound EI-1 were then introduced into the other two cells, and respectively evaporated at a rate of 1:1 to form an electron transport layer having a thickness of 35 nm on the light-emitting layer. After depositing compound EI-1 as an electron injection layer having a thickness of 2 nm on the electron transport layer, an Al cathode having a thickness of 80 nm was deposited on the electron injection layer by another vacuum vapor deposition apparatus. Thus, an OLED device was produced.

### [Comparative Example 1-1] Producing an OLED Device Comprising a Host Compound of the Present Disclosure, but not Comprising Compounds of a Hole Transport Layer Having HOMO and LUMO Energy Levels According to the Present Disclosure

An OLED device was produced in the same manner as in Device Example 1-1, except that compounds not having HOMO and LUMO energy values of the present disclosure were used for the second hole transport layer, but the compound described in the following Table 2 as a host, i.e., quinoxaline derivative, was comprised.

### [Comparative Example 2-1] Producing an OLED Device Comprising Compounds of a Hole Transport Layer Having HOMO and LUMO Energy Levels According to the Present Disclosure, but not Comprising Quinoxaline Derivatives as a Host Compound

OLED device was produced in the same manner as in Device Example 1-1, except that the compound described in the following Table 2 as a host, i.e., not a quinoxaline derivative, was comprised.

The current efficiency at a luminance of 1,000 nits and the time taken for the light-emission to be reduced from 100% to 98% at a luminance of 5,000 nit (lifespan; T98) of the organic electroluminescent device of Device Examples 1-1 to 1-6, and Comparative Examples 1-1 and 2-1 produced as above are shown in the following Table 2.

TABLE 2

| | | | Current | |
|---|---|---|---|---|
| | Second Hole | | Efficiency | Lifespan |
| | Transport Layer | Host | (cd/A) | (T98, hr) |
| Device Example 1-1 | HT-2 | RH-4 | 27.1 | 103 |
| Device Example 1-2 | HT-3 | RH-4 | 26.7 | 112 |
| Device Example 1-3 | HT-4 | RH-4 | 27.8 | 109 |
| Device Example 1-4 | HT-5 | RH-4 | 25.6 | 84 |
| Device Example 1-5 | HT-9 | RH-4 | 25.6 | 86 |
| Device Example 1-6 | HT-10 | RH-4 | 25.8 | 100 |
| Comparative Example | HT-6 | RH-4 | 20.1 | 22 |
| 1-1 | | | | |
| Comparative Example | HT-5 | RH-5 | 15.7 | 65 |
| 2-1 | | | | |

### [Device Examples 2-1 to 2-3] Producing an OLED Device According to the Present Disclosure

OLED devices were produced in the same manner as in Device Example 1-1, except that the compounds described in the following Table 3, as a second hole transport layer material and a host, were comprised.

### [Comparative Example 1-2] Producing an OLED Device Comprising a Host Compound of the Present Disclosure, but not Comprising Compounds of a Hole Transport Layer Having HOMO and LUMO Energy Levels According to the Present Disclosure

An OLED device was produced in the same manner as in Device Example 2-1, except that the compound described in the following Table 3, as a second hole transport layer material, was comprised.

### [Comparative Example 2-2] Producing an OLED Device Comprising Compounds of a Hole Transport Layer Having HOMO and LUMO Energy Levels According to the Present Disclosure, but Comprising a Host Compound Having No Quinoxaline LUMO Moiety

An OLED device was produced in the same manner as in Device Example 2-1, except that the compound described in the following Table 3, as a host, was comprised.

The current efficiency at a luminance of 1,000 nits of OLED device of Device Examples 2-1 to 2-3, and Comparative Examples 1-2 and 2-2 produced above is shown in the following Table 3.

TABLE 3

| | Second Hole | | Current Efficiency |
|---|---|---|---|
| | Transport Layer | Host | (cd/A) |
| Device Example 2-1 | HT-5 | RH-6 | 27.1 |
| Device Example 2-2 | HT-7 | RH-6 | 25.7 |
| Device Example 2-3 | HT-8 | RH-6 | 26.9 |
| Comparative Example | HT-6 | RH-6 | 19.2 |
| 1-2 | | | |
| Comparative Example | HT-5 | RH-7 | 17.0 |
| 2-2 | | | |

HOMO and LUMO energy levels of compounds described in Tables 2 and 3 above are shown in the following Table 4.

TABLE 4

| Compound | HOMO (eV) | LUMO (eV) |
|---|---|---|
| HT-2 | −4.788 | −1.054 |
| HT-3 | −4.859 | −1.001 |
| HT-4 | −4.836 | −1.365 |
| HT-5 | −4.752 | −1.242 |
| HT-7 | −4.784 | −1.264 |
| HT-8 | −4.799 | −1.126 |
| HT-6 | −4.469 | −0.635 |
| HT-9 | −4.942 | −1.114 |
| HT-10 | −4.767 | −0.989 |

From Tables 2 to 4 above, it was confirmed that an OLED device exhibits high efficiency and/or long lifespan characteristics when a compound(s) having HOMO and LUMO energy levels of the present disclosure is used in the hole transport layer adjacent to the light-emitting layer while using quinoxaline derivative as a host. Particularly, an OLED device comprising a specific combination of the light-emitting layer and the hole transport layer of the present disclosure may be suitable for a flexible display, a lighting, and a display for an automobile that require high efficiency and/or long lifespan.

### [Comparative Example 3-1] Producing an OLED not According to the Present Disclosure

An OLED device not according to the present disclosure was produced. First, a transparent electrode indium tin oxide (ITO) thin film (10 Ω/sq) on a glass substrate for an OLED (GEOMATEC CO., LTD., Japan) was subjected to an ultrasonic washing with acetone and isopropyl alcohol, sequentially, and then was stored in isopropanol. Next, the ITO substrate was mounted on a substrate holder of a vacuum vapor deposition apparatus. Compound HI-1 was introduced into a cell of the vacuum vapor deposition apparatus, and the pressure in the chamber of the apparatus was then controlled to 10^{0.7} torr. Thereafter, an electric current was applied to the cell to evaporate the introduced material, thereby forming a first hole injection layer having a thickness of 80 nm on the ITO substrate. Compound HI-2 was then introduced into another cell of the vacuum vapor deposition apparatus, and an electric current was applied to the cell to evaporate the introduced material, thereby forming a second hole injection layer having a thickness of 5 nm on the first hole injection layer. Next, compound HT-1 was introduced into another cell of the vacuum vapor deposition apparatus. Thereafter, an electric current was applied to the cell to evaporate the introduced material, thereby forming a first hole transport layer having a thickness of 10 nm on the second hole injection layer. Compound HT-3 was then introduced into another cell of the vacuum vapor deposition apparatus, and an electric current was applied to the cell to evaporate the introduced material, thereby forming a second hole transport layer having a thickness of 60 nm on the first hole transport layer. After forming the hole injection layers and the hole transport layers, a light-emitting layer was then deposited as follows. Compound RH-4 as a host was introduced into one cell of the vacuum vapor deposition apparatus and compound RD-1 as a dopant was introduced into another cell of the apparatus. The two materials were evaporated at a different rate and the dopant was deposited in a doping amount of 3 wt %, based on the total weight of the host and dopant, to form a light-emitting layer having a thickness of 40 nm on the second hole transport layer. Next, compound ET-2 (BCP) as an electron transport material was introduced into one cell and evaporated to form an electron transport layer having a thickness of 35 nm. Afterward, compound EI-1 as an electron injection layer having a thickness of 2 nm was deposited on the electron transport layer, and an Al cathode having a thickness of 80 nm was deposited on the electron injection layer by another vacuum vapor deposition apparatus. Thus, an OLED device was produced. All the materials used for producing the OLED device were purified by vacuum sublimation at 10⁻⁶ torr.

### [Device Examples 3-1 to 3-7] Producing an OLED Device According to the Present Disclosure

In Device Examples 3-1 to 3-7, an OLED device were produced in the same manner as in Comparative Example 3-1, except that each of the compounds described in the following Table 5 in a weight ratio of 50:50 was deposited to form an electron transport layer having a thickness of 35 nm.

The driving voltage, the luminous efficiency, and the CIE color coordinates at a luminance of 1,000 nits and the time taken for the light-emission to be reduced from 100% to 90% at a luminance of 5,000 nit (lifespan; T90) of the organic electroluminescent device of Comparative Example 3-1, and Device Examples 3-1 to 3-7, produced as above are shown in the following Table 5.

TABLE 5

| | Electron | Electron | Driving | Luminous | Color | | |
|---|---|---|---|---|---|---|---|
| | Buffer | Transport | Voltage | Efficiency | Coordinates | | Lifespan |
| | Layer | Layer | (V) | (cd/A) | (x) | (y) | (T90, hr) |
| Comparative | — | ET-2 | 5.5 | 20.3 | 0.660 | 0.340 | 0.2 |
| Example 3-1 | | | | | | | |
| Device | — | ET-3: EI-1 | 3.3 | 25.9 | 0.663 | 0.337 | 750.8 |
| Example 3-1 | | | | | | | |
| Device | — | ET-4: EI-1 | 3.2 | 26.0 | 0.663 | 0.337 | 775.3 |
| Example 3-2 | | | | | | | |
| Device | — | ET-5: EI-1 | 3.1 | 26.2 | 0.663 | 0.336 | 726.9 |
| Example 3-3 | | | | | | | |
| Device | — | ET-6: EI-1 | 3.1 | 26.0 | 0.663 | 0.337 | 919.4 |
| Example 3-4 | | | | | | | |
| Device | — | ET-7: EI-1 | 3.1 | 25.3 | 0.663 | 0.337 | 783.7 |
| Example 3-5 | | | | | | | |
| Device | — | ET-8: EI-1 | 3.2 | 25.6 | 0.663 | 0.337 | 1075.7 |
| Example 3-6 | | | | | | | |
| Device | — | ET-1: EI-1 | 3.1 | 26.2 | 0.664 | 0.336 | 1280.4 |
| Example 3-7 | | | | | | | |

### [Device Examples 4-1 to 4-3] Producing an OLED Device According to the Present Disclosure

In Device Examples 4-1 to 4-3, OLED devices were produced in the same manner as in Comparative Example 3-1, except that compound EB-1 was deposited to form an electron buffer layer having a thickness of 5 nm on the light-emitting layer and then each of the compounds described in the following Table 6 in a weight ratio of 50:50 was deposited to form an electron transport layer having a thickness of 30 nm on the electron buffer layer.

The driving voltage, the luminous efficiency, and the CIE color coordinates at a luminance of 1,000 nits and the time taken for the light-emission to be reduced from 100% to 80% at a luminance of 5,000 nit (lifespan; T80) of the organic electroluminescent device of Device Examples 4-1 to 4-3, produced as above are shown in the following Table 6.

TABLE 6

| | Electron | Electron | Driving | Luminous | Color | | |
|---|---|---|---|---|---|---|---|
| | Buffer | transport | Voltage | Efficiency | Coordinates | | Lifespan |
| | Layer | Layer | (V) | (cd/A) | (x) | (y) | (T80, hr) |
| Device | EB-1 | ET-9: EI-1 | 3.0 | 23.8 | 0.663 | 0.337 | 1114.3 |
| Example 4-1 | | | | | | | |
| Device | EB-1 | ET-10: EI-1 | 3.1 | 24.0 | 0.662 | 0.337 | 1127.8 |
| Example 4-2 | | | | | | | |
| Device | EB-1 | ET-11: EI-1 | 3.1 | 24.2 | 0.663 | 0.337 | 1238.8 |
| Example4-3 | | | | | | | |

LUMO energy levels of compounds described in Tables 5 and 6 above are shown in the following Table 7.

TABLE 7

| Compound | LUMO (eV) |
|---|---|
| ET-1 | −1.888 |
| ET-2 | −1.285 |
| ET-3 | −1.882 |
| ET-4 | −1.991 |
| ET-5 | −1.912 |
| ET-6 | −1.904 |
| ET-7 | −1.999 |
| ET-8 | −2.051 |
| ET-9 | −1.908 |
| ET-10 | −2.110 |
| ET-11 | −2.047 |
| EB-1 | −1.957 |

From Tables 5 to 7 above, it was confirmed that Device Examples 3-1 to 3-7 and 4-1 to 4-3 comprising a compound having −1.5 eV or less of LUMO energy level comprised in the electron transport layer and/or the electron buffer layer and using quinoxaline derivative as a host exhibit low driving voltage, high efficiency and/or long lifespan compared with Comparative Example 3-1. In addition, it can be seen that the OLED device comprising a triazine derivative in the electron transport layer and/or the electron buffer layer exhibits a lower driving voltage, higher efficiency, and/or long lifespan characteristic than the OLED device not comprising a triazine derivative.

The compounds used in the Comparative Examples and Device Examples are shown in Table 8 below.

TABLE 8

| | |
|---|---|
| Hole Blocking Layer | 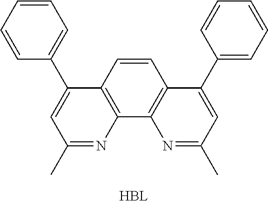 [SMILES: Cc1cc(-c2ccccc2)c2ccc3c(-c4ccccc4)cc(C)nc3c2n1] |
| Hole Injection Layer/Hole Transport Layer | 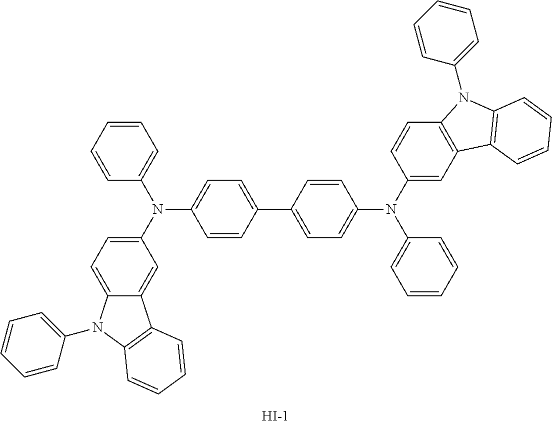 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1] |
| | 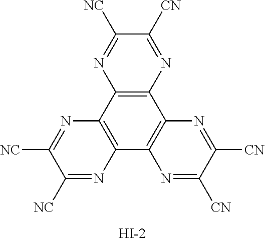 [SMILES: N#Cc1nc2c3nc(C#N)c(C#N)nc3c3nc(C#N)c(C#N)nc3c2nc1C#N] |
| | 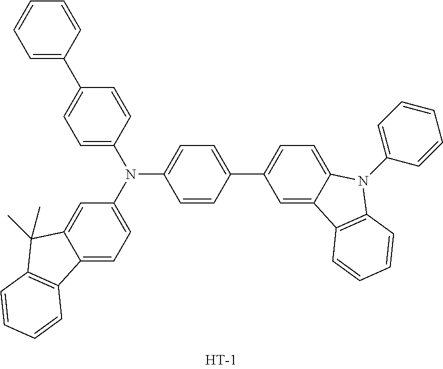 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21] |
| | 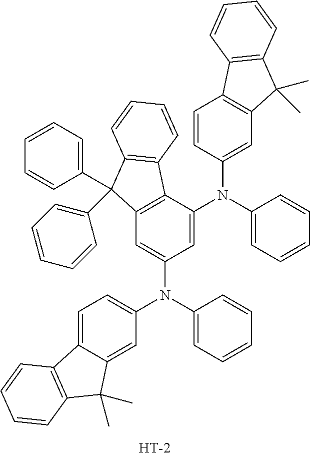 [SMILES: CC1(C)c2ccccc2-c2ccc(N(c3ccccc3)c3cc(N(c4ccccc4)c4ccc5c(c4)C(C)(C)c4ccccc4-5)c4c(c3)C(c3ccccc3)(c3ccccc3)c3ccccc3-4)cc21] |
| | 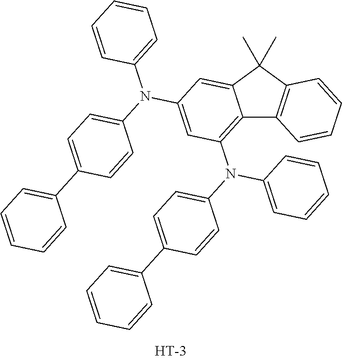 [SMILES: CC1(C)c2ccccc2-c2c(N(c3ccccc3)c3ccc(-c4ccccc4)cc3)cc(N(c3ccccc3)c3ccc(-c4ccccc4)cc3)cc21] |
| | 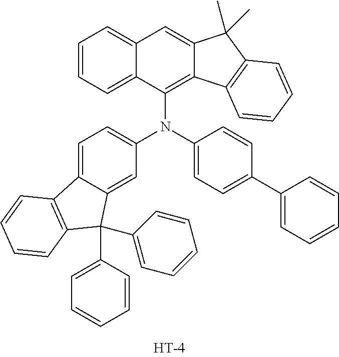 [SMILES: CC1(C)c2ccccc2-c2c1cc1ccccc1c2N(c1ccc(-c2ccccc2)cc1)c1ccc2c(c1)C(c1ccccc1)(c1ccccc1)c1ccccc1-2] |
| | 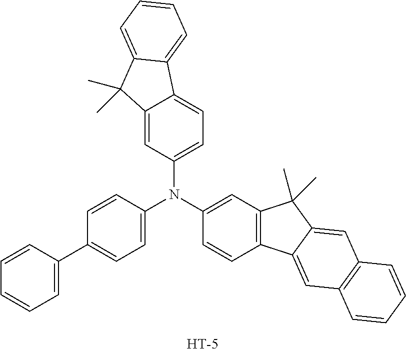 [SMILES: CC1(C)c2ccccc2-c2ccc(N(c3ccc(-c4ccccc4)cc3)c3ccc4c(c3)C(C)(C)c3cc5ccccc5cc3-4)cc21] |
| | 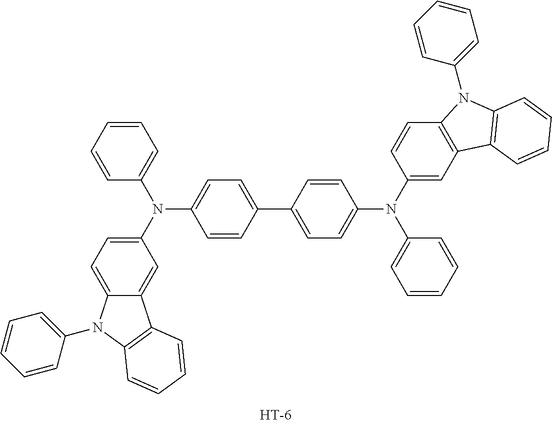 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1] |
| | 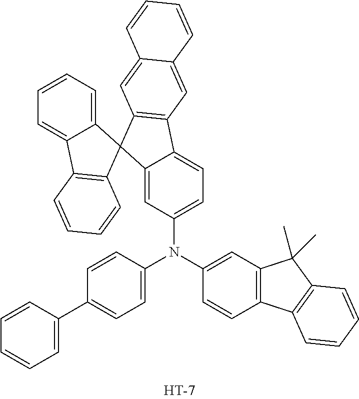 [SMILES: CC1(C)c2ccccc2-c2ccc(N(c3ccc(-c4ccccc4)cc3)c3ccc4c(c3)C3(c5ccccc5-c5ccccc53)c3cc5ccccc5cc3-4)cc21] |
| | 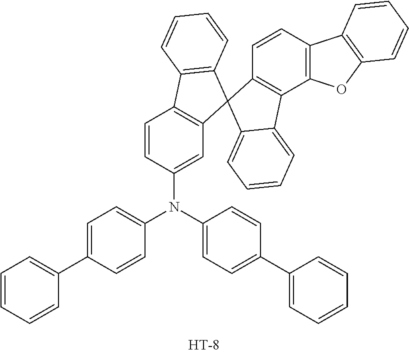 [SMILES: c1ccc(-c2ccc(N(c3ccc(-c4ccccc4)cc3)c3ccc4c(c3)C3(c5ccccc5-4)c4ccccc4-c4c3ccc3c4oc4ccccc43)cc2)cc1] |
| | 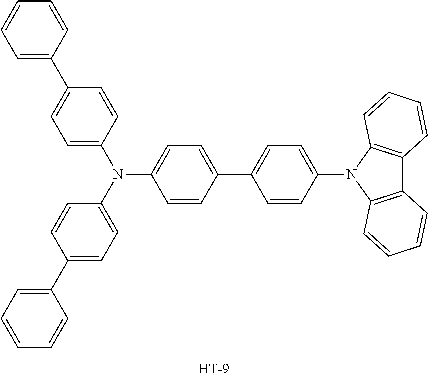 [SMILES: c1ccc(-c2ccc(N(c3ccc(-c4ccccc4)cc3)c3ccc(-c4ccc(-n5c6ccccc6c6ccccc65)cc4)cc3)cc2)cc1] |
| | 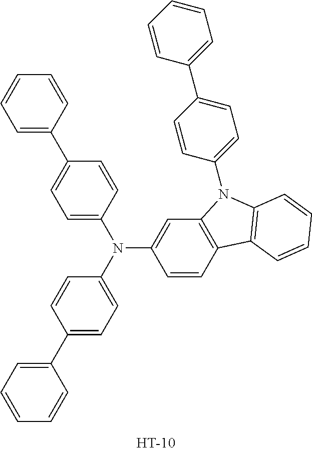 [SMILES: c1ccc(-c2ccc(N(c3ccc(-c4ccccc4)cc3)c3ccc4c5ccccc5n(-c5ccc(-c6ccccc6)cc5)c4c3)cc2)cc1] |
| Light-Emitting Layer (Host) | 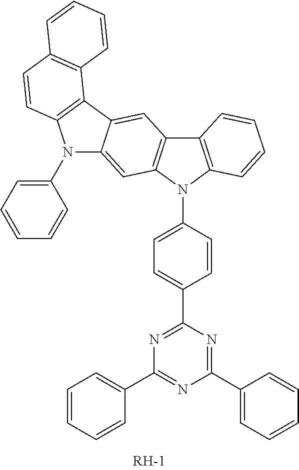 [SMILES: c1ccc(-c2nc(-c3ccccc3)nc(-c3ccc(-n4c5ccccc5c5cc6c7c8ccccc8ccc7n(-c7ccccc7)c6cc54)cc3)n2)cc1] |
| | 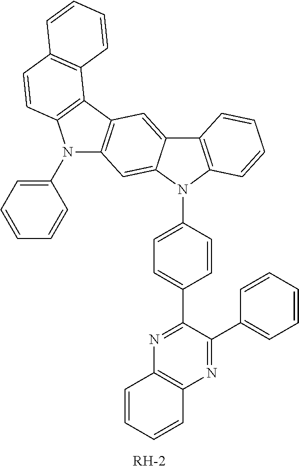 [SMILES: c1ccc(-c2nc3ccccc3nc2-c2ccc(-n3c4ccccc4c4cc5c6c7ccccc7ccc6n(-c6ccccc6)c5cc43)cc2)cc1] |
| | 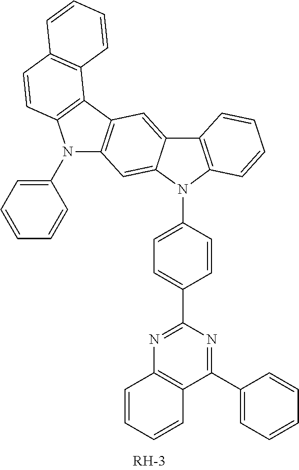 [SMILES: c1ccc(-c2nc(-c3ccc(-n4c5ccccc5c5cc6c7c8ccccc8ccc7n(-c7ccccc7)c6cc54)cc3)nc3ccccc23)cc1] |
| | 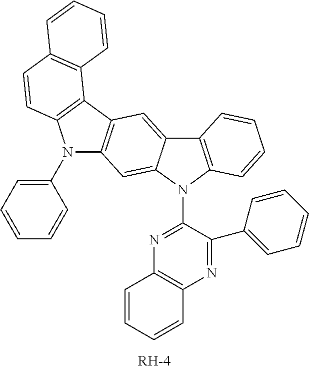 [SMILES: c1ccc(-c2nc3ccccc3nc2-n2c3ccccc3c3cc4c5c6ccccc6ccc5n(-c5ccccc5)c4cc32)cc1] |
| | 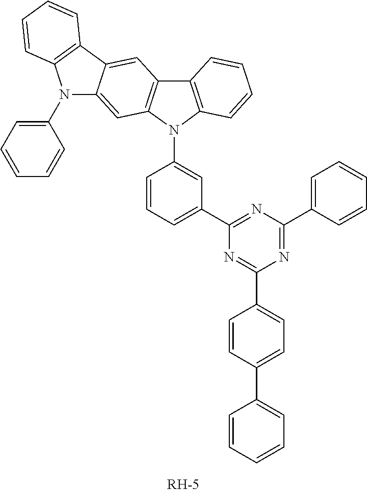 [SMILES: c1ccc(-c2ccc(-c3nc(-c4ccccc4)nc(-c4cccc(-n5c6ccccc6c6cc7c8ccccc8n(-c8ccccc8)c7cc65)c4)n3)cc2)cc1] |
| | 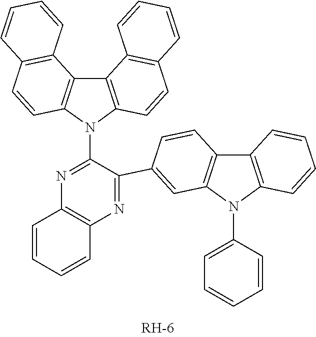 [SMILES: c1ccc(-n2c3ccccc3c3ccc(-c4nc5ccccc5nc4-n4c5ccc6ccccc6c5c5c6ccccc6ccc54)cc32)cc1] |
| | 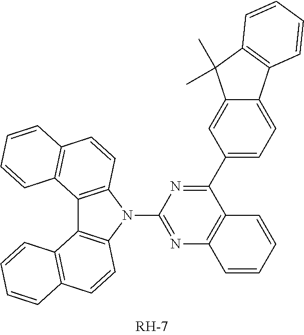 [SMILES: CC1(C)c2ccccc2-c2ccc(-c3nc(-n4c5ccc6ccccc6c5c5c6ccccc6ccc54)nc4ccccc34)cc21] |
| Light-Emitting Layer (Dopant) | 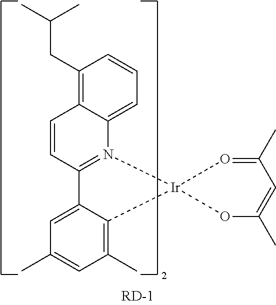 |
| Electron Buffer Layer | 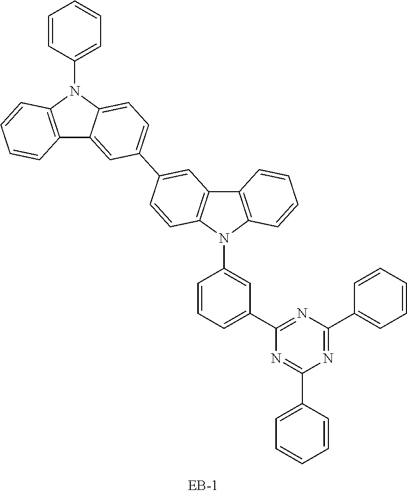 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1] |
| Electron Transport Layer/Electron Injection Layer | 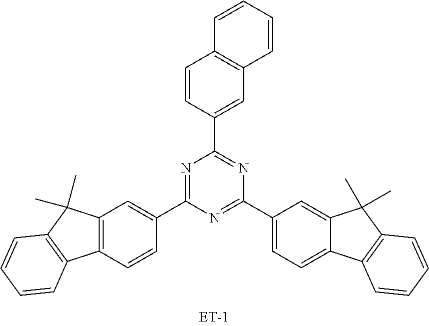 [SMILES: CC1(C)c2ccccc2-c2ccc(-c3nc(-c4ccc5c(c4)C(C)(C)c4ccccc4-5)nc(-c4ccc5ccccc5c4)n3)cc21] |
| | 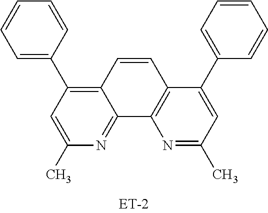 [SMILES: Cc1cc(-c2ccccc2)c2ccc3c(-c4ccccc4)cc(C)nc3c2n1] |
| | 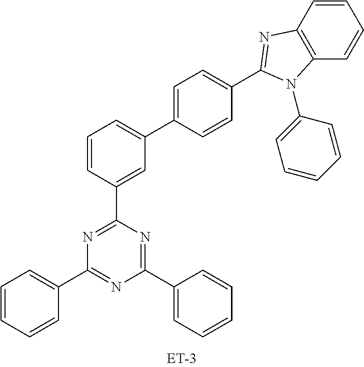 [SMILES: c1ccc(-c2nc(-c3ccccc3)nc(-c3cccc(-c4ccc(-c5nc6ccccc6n5-c5ccccc5)cc4)c3)n2)cc1] |
| | 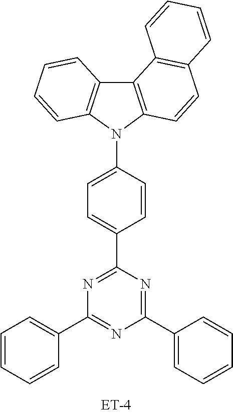 [SMILES: c1ccc(-c2nc(-c3ccccc3)nc(-c3ccc(-n4c5ccccc5c5c6ccccc6ccc54)cc3)n2)cc1] |
| | 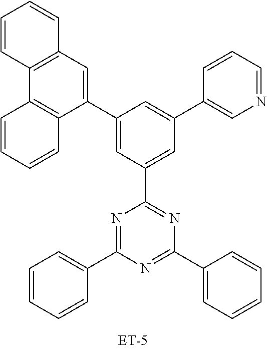 [SMILES: c1ccc(-c2nc(-c3ccccc3)nc(-c3cc(-c4cccnc4)cc(-c4cc5ccccc5c5ccccc45)c3)n2)cc1] |
| | 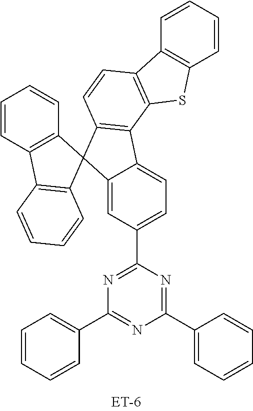 [SMILES: c1ccc(-c2nc(-c3ccccc3)nc(-c3ccc4c(c3)C3(c5ccccc5-c5ccccc53)c3ccc5c(sc6ccccc65)c3-4)n2)cc1] |
| | 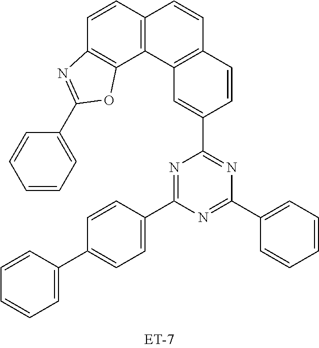 [SMILES: c1ccc(-c2ccc(-c3nc(-c4ccccc4)nc(-c4ccc5ccc6ccc7nc(-c8ccccc8)oc7c6c5c4)n3)cc2)cc1] |
| | 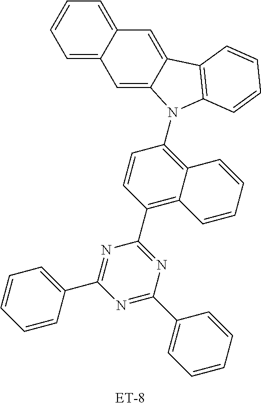 [SMILES: c1ccc(-c2nc(-c3ccccc3)nc(-c3ccc(-n4c5ccccc5c5cc6ccccc6cc54)c4ccccc34)n2)cc1] |
| | 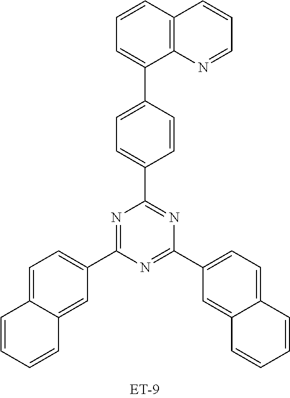 [SMILES: c1ccc2cc(-c3nc(-c4ccc(-c5cccc6cccnc56)cc4)nc(-c4ccc5ccccc5c4)n3)ccc2c1] |
| | 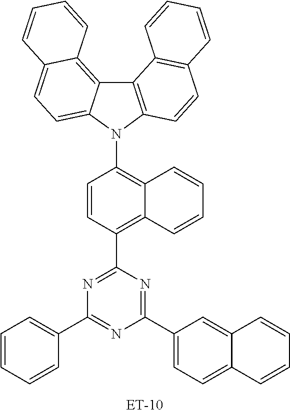 [SMILES: c1ccc(-c2nc(-c3ccc4ccccc4c3)nc(-c3ccc(-n4c5ccc6ccccc6c5c5c6ccccc6ccc54)c4ccccc34)n2)cc1] |
| | 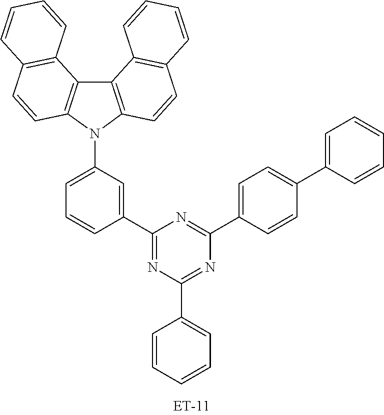 [SMILES: c1ccc(-c2ccc(-c3nc(-c4ccccc4)nc(-c4cccc(-n5c6ccc7ccccc7c6c6c7ccccc7ccc65)c4)n3)cc2)cc1] |
| | 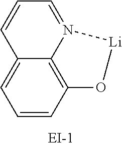 |

1. An organic electroluminescent device comprising a first electrode; a second electrode facing the first electrode; a light-emitting layer between the first electrode and the second electrode; a hole transport zone comprising a plurality of hole transport layers between the first electrode and the light-emitting layer; and an electron transport zone between the light-emitting layer and the second electrode, wherein the light-emitting layer comprises quinoxaline derivatives, and wherein a hole transport layer adjacent to the light-emitting layer among the plurality of hole transport layers comprises a compound(s) having HOMO and LUMO energy levels satisfied by the following Equations 1 and 2, respectively.
−5.0 eV≤HOMO≤−4.7 eV (1)
LUMO≤−1.0 eV (2)

2. The organic electroluminescent device according to claim 1, wherein the hole transport zone further comprises at least one of a hole injection layer, a hole auxiliary layer, a light-emitting auxiliary layer, and an electron blocking layer.

3. The organic electroluminescent device according to claim 1, wherein the hole transport layer adjacent to the light-emitting layer comprises at least one carbazole-based arylamine derivative and at least one arylamine derivative that does not contain carbazole, and wherein each of the carbazole-based arylamine derivatives may be the same or different from each other, and each of the arylamine derivatives not containing carbazole may be the same or different from each other.

4. The organic electroluminescent device according to claim 3, wherein the carbazole-based arylamine derivative contains at least one of the compounds represented by the following formulae 1 and 2: 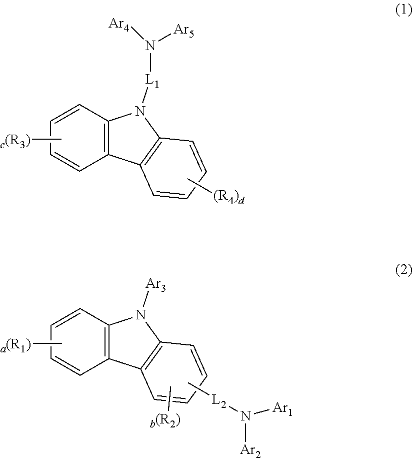
wherein,
Aᵣ to Ar₅ each independently represent a substituted or unsubstituted (C6-C30)aryl, or a substituted or unsubstituted (5- to 30-membered)heteroaryl,
L₁ and L₂ each independently represent a single bond or a substituted or unsubstituted (C6-C30)arylene,
R₁ to R₄ each independently represent hydrogen, deuterium, halogen, a substituted or unsubstituted (C1-C30)alkyl, a substituted or unsubstituted (C6-C30)aryl, a substituted or unsubstituted (5- to 30-membered)heteroaryl, a substituted or unsubstituted (C3-C30)cycloalkyl, a substituted or unsubstituted (3- to 7-membered)heterocycloalkyl, a substituted or unsubstituted (C6-C30)ar(C1-C30)alkyl, —NR₁₁R₁₂, —SiR₁₃R₁₄R₁₅, —SR₁₆, —OR₁₇, cyano, nitro, or hydroxy; or may be linked to an adjacent substituent to form a substituted or unsubstituted, (C3-C30) mono- or polycyclic, alicyclic, aromatic ring, or the combination thereof, whose carbon atom may be replaced with at least one heteroatom selected from nitrogen, oxygen, and sulfur,
R₁₁ to R₁₇ each independently represent hydrogen, deuterium, halogen, a substituted or unsubstituted (C1-C30)alkyl, a substituted or unsubstituted (C6-C30)aryl, a substituted or unsubstituted (5- to 30-membered)heteroaryl, a substituted or unsubstituted (3- to 7-membered)heterocycloalkyl, or a substituted or unsubstituted (C3-C30)cycloalkyl; or may be linked to an adjacent substituent to form a substituted or unsubstituted, (C3-C30) mono- or polycyclic, alicyclic, aromatic ring, or the combination thereof, whose carbon atom may be replaced with at least one heteroatom selected from nitrogen, oxygen, and sulfur,
a, c, and d each independently represent an integer of 1 to 4, b represents an integer of 1 to 3, and where a to d each represent an integer of 2 or more, each of R, to R₄ may be the same or different,
the heteroaryl contains at least one heteroatom selected from B, N, O, S, Si, and P.

5. The organic electroluminescent device according to claim 3, wherein the arylamine derivative not containing carbazole contains at least one of the compounds represented by the following formulae 3 and 4: 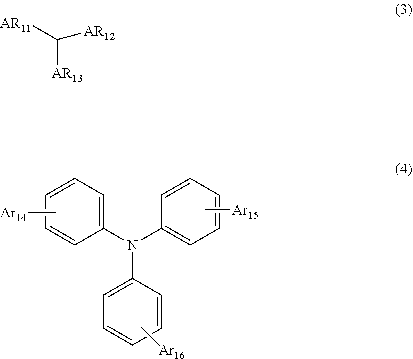
wherein,
Ar₁₁ to Ar₁₃ each independently represent a substituted or unsubstituted (C6-C30)aryl, or a substituted or unsubstituted (5- to 50-membered)heteroaryl, provided that at least one of Ar₁₁ to Ar₁₃ contains fluorene derivative,
Ar₁₄ to Ar₁₆ each independently represent a substituted or unsubstituted (C6-C30)aryl, a substituted or unsubstituted (5- to 30-membered)heteroaryl, or a substituted or unsubstituted (C6-C30)arylamine; or may be linked to an adjacent substituent to form a substituted or unsubstituted ring,
the heteroaryl contains at least one heteroatom selected from B, N, O, S, Si, and P.

6. The organic electroluminescent device according to claim 1, wherein the electron transport zone comprises a compound having LUMO energy levels (Ae) satisfied by the following Equation 3.
Ae≤−1.5 eV (3)

7. The organic electroluminescent device according to claim 1, wherein the electron transport zone further comprises at least one of an electron buffer layer, a hole blocking layer, an electron transport layer, and an electron injection layer.

8. The organic electroluminescent device according to claim 1, wherein the electron transport zone comprises at least one triazine derivative, wherein each of the triazine derivatives may be the same or different from each other.

9. The organic electroluminescent device according to claim 8, wherein the triazine derivative contains a compound represented by the following formula 5: 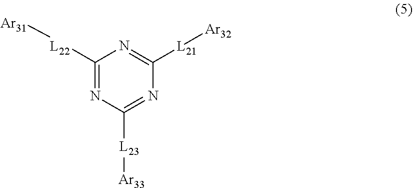
wherein,
L₂₁ to L₂₃ each independently represent a single bond, a substituted or unsubstituted (C6-C50)arylene, or a substituted or unsubstituted (5- to 50-membered)heteroarylene,
Ar₃₁ to Ar₃₃ each independently represent hydrogen, deuterium, a substituted or unsubstituted (C6-C50)aryl, or a substituted or unsubstituted (5- to 50-membered)heteroaryl,
the heteroaryl(ene) contains at least one heteroatom selected from B, N, O, S, Si, and P.

10. A display device comprising the organic electroluminescent device according to claim 1.
